(19) United States
(12) Patent Application Publication
(10) Pub. No.: US 2025/0331308 A1
(43) Pub. Date: Oct. 23, 2025

(54) ELECTRONIC DEVICE

(71) Applicant: Innolux Corporation, Miaoli County (TW)

(72) Inventors: Shih-Siang Yan, Miaoli County (TW); Kung-Chen Kuo, Miaoli County (TW); Yi-Hung Lin, Miaoli County (TW); Wen-Chieh Lin, Miaoli County (TW)

(73) Assignee: Innolux Corporation, Miaoli County (TW)

(21) Appl. No.: 19/084,692

(22) Filed: Mar. 19, 2025

Related U.S. Application Data
(60) Provisional application No. 63/636,112, filed on Apr. 19, 2024.

(30) Foreign Application Priority Data
Sep. 24, 2024 (CN) 202411335098.6

(51) Int. Cl. H10D 89/60; H10D 1/64

(52) U.S. Cl. CPC H10D 89/611; H10D 1/64

(57) ABSTRACT

An electronic device is provided. The electronic device includes a bonding point, an electrostatic discharge protection circuit and a scan transistor. The electrostatic discharge protection circuit is electrically connected to the bonding point. The scan transistor has a first terminal, a second terminal and a control terminal. The second terminal of the scan transistor is electrically connected to the bonding point and the electrostatic discharge protection circuit.

### CROSS-REFERENCE TO RELATED APPLICATION

This application claims the priority benefit of U.S. provisional application Ser. No. 63/636,112, filed on Apr. 19, 2024 and China application serial no. 202411335098.6, filed on Sep. 24, 2024. The entirety of each of the above-mentioned patent applications is hereby incorporated by reference herein and made a part of this specification.

### BACKGROUND

### Technical Field

The disclosure relates to a device, and more particularly to an electronic device with electrostatic protection function.

### Description of Related Art

Generally, after the manufacturing process of a panel device (such as a display panel or an antenna device), a tunable unit (such as a liquid crystal unit or a varactor diode) is connected to the joints (i.e. the bonding points) of each unit in a panel. However, during the manufacturing process, the joint of each unit in the panel are exposed, so electrostatic discharge (ESD) is easily generated at the joints, resulting in a large electrostatic current, thereby causing damage to other electronic components electrically connected to the joints.

### SUMMARY

The disclosure is directed to an electronic device having an electrostatic protection structure and realizing good electrostatic protection function.

The electronic device of the disclosure includes a bonding point, an electrostatic discharge protection circuit and a scan transistor. The electrostatic discharge protection circuit is electrically connected to the bonding point. The scan transistor has a first terminal, a second terminal and a control terminal. The second terminal of the scan transistor is electrically connected to the bonding point and the electrostatic discharge protection circuit.

Based on the above, the electronic device of the disclosure may release the electrostatic current generated in the bonding point through the electrostatic discharge protection circuit to effectively protect other electronic components electrically connected to the bonding point.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of an electronic device according to an embodiment of the disclosure.

FIG. 2 is a circuit diagram of an electronic device according to an embodiment of the disclosure.

FIG. 3 is a circuit diagram of an electronic device according to an embodiment of the disclosure.

FIG. 4 is a circuit diagram of an electronic device according to an embodiment of the disclosure. FIG. 5 is a circuit diagram of an electronic device according to an embodiment of the disclosure.

FIG. 6 is a circuit diagram of an electronic device according to an embodiment of the disclosure.

FIG. 7 is a circuit diagram of an electronic device according to an embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as “comprise” and “include” are open-ended terms, and should be explained as “including but not limited to . . . ”.

Although the terms first, second, third . . . may be used to describe various constituent elements, the constituent elements are not limited to these terms. This term is only used to distinguish a single component from other components in the specification. The same terms may not be used in the claims, but may be replaced by first, second, third . . . according to the order in which the elements are declared in the claims. Therefore, in the following description, a first constituent element may be a second constituent element in the claims.

In some embodiments of the disclosure, terms related to joining and connecting, such as “connection”, “interconnection”, etc., unless otherwise defined, may mean that two structures are in direct contact, or may also mean that two structures are not in direct contact. There are other structures located between these two structures. Moreover, the terms about joining and connecting may also include the situation where both structures are movable, or both structures are fixed.

In some embodiments of the disclosure, the electronic device may include a display device, an antenna device, a sensing device or a splicing device, but is not limited thereto. The electronic device may include, for example, a liquid crystal light emitting diode. The light emitting diode may include, for example, an organic light emitting diode (OLED), a sub-millimeter light emitting diode (mini LED), a micro light emitting diode (micro LED), a quantum dot light emitting diode (QD) (and may be, for example, QLED or QDLED), fluorescence, phosphorescence or other suitable materials, and the materials may be arranged and combined at will, but are not limited to this. The antenna device may be, for example, a liquid crystal antenna, but is not limited thereto. The splicing device may be, for example, a display splicing device or an antenna splicing device, but is not limited thereto. It should be noted that the electronic device may be any combination of the above, but is not limited thereto. In the following, a display device will be used as an electronic device or a splicing device to illustrate the disclosure, but the disclosure is not limited thereto.

It should be noted that in the following embodiments, the technical features in several different embodiments may be replaced, reorganized, and mixed to complete other embodiments without departing from the spirit of the disclosure.

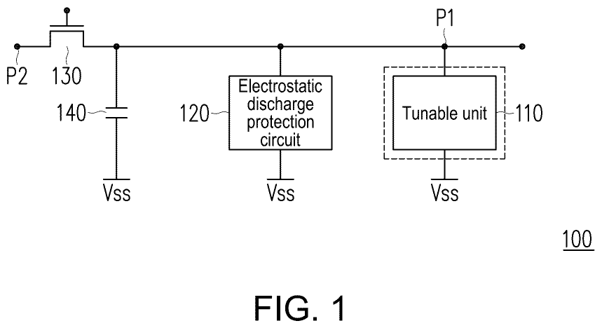

FIG. 1 is a schematic diagram of an electronic device according to an embodiment of the disclosure. Referring to FIG. 1, the electronic device 100 includes a bonding point P1 (or circuit node), a tunable unit 110, an electrostatic discharge (ESD) protection circuit 120, a scan transistor 130 and a storage capacitor 140. The scan transistor 130 may be an N-type or P-type thin-film transistor (TFT). The scan transistor 130 has a first terminal, a second terminal and a control terminal. In the embodiment, the first terminal of the scan transistor 130 is electrically connected to the circuit node P2. The circuit node P2 may also be electrically connected to other functional circuits of the electronic device 100, such as a driving circuit, but the disclosure is not limited thereto. The second terminal of the scan transistor 130 is electrically connected to the bonding point P1, the tunable unit 110, the electrostatic discharge protection circuit 120 and the storage capacitor 140. In the embodiment, the tunable unit 110 is electrically connected between the bonding point P1 and the operation voltage VSS. The operation voltage VSS may have a low voltage level or be a ground voltage. The electrostatic discharge protection circuit 120 is electrically connected between the bonding point P1 and the operation voltage VSS. The storage capacitor 140 is electrically connected between the bonding point P1 and the tunable unit 110.

It should be noted that, during the manufacturing process of the electronic device 100, the electrostatic discharge protection circuit 120 is first formed in the electronic device 100 before disposing the tunable unit 110 to serve as (or form) a discharge path for the bonding point P1 and/or the scan transistor 130. In other words, in some embodiments of the disclosure, the electronic device 100 may not include the tunable unit 110. Furthermore, in some embodiments of the disclosure, when the electronic device 100 is operating, the control terminal of the scan transistor 130 may be used to receive a scan signal, and the first terminal of the scan transistor 130 may receive a driving signal (e.g. having a data voltage). The scan transistor 130 may write a driving signal into the storage capacitor 140 according to the scan signal to drive the tunable unit 110. The voltage value of the driving signal (i.e. the data voltage) may be higher than the voltage value of the operation voltage VSS.

In addition, in some embodiments of the disclosure, the electronic device 100 may include a substrate, and a plurality of pixel units may be formed on the substrate, wherein each of the plurality of pixel units may include the bonding point P1, the tunable unit 110, the electrostatic discharge protection circuit 120, the scan transistor 130, and the storage capacitor 140 as shown in FIG. 1.

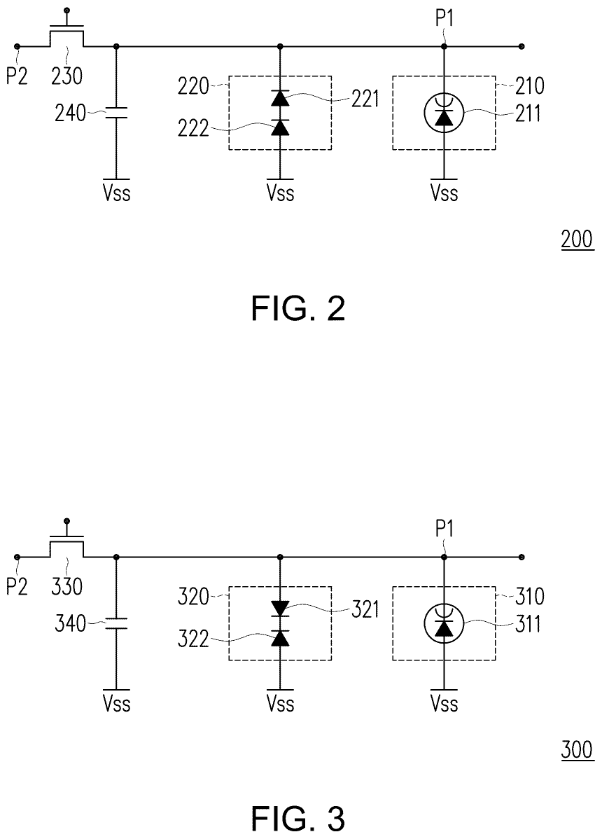

FIG. 2 is a circuit diagram of an electronic device according to an embodiment of the disclosure. Referring to FIG. 2, the electronic device 200 includes a bonding point P1, a tunable unit 210, an electrostatic discharge protection circuit 220, a scan transistor 230, and a storage capacitor 240. The scan transistor 230 has a first terminal, a second terminal and a control terminal. In the embodiment, the first terminal of the scan transistor 230 is electrically connected to the circuit node P2. The second terminal of the scan transistor 230 is electrically connected to the bonding point P1, the tunable unit 210, the electrostatic discharge protection circuit 220 and the storage capacitor 240. In the embodiment, the tunable unit 210 includes a varactor diode 211. The first terminal of the varactor diode 211 is electrically connected to the bonding point P1. The second terminal of the varactor diode 211 is electrically connected to the operation voltage Vss. The electrostatic discharge protection circuit 220 includes a first diode 221 and a second diode 222. The first diode 221 is electrically connected to the bonding point P1 and the second terminal of the scan transistor 230. The second diode 222 is electrically connected to the first diode 221. The first diode 221 and the second diode 222 are connected in series. The cathode of the first diode 221 is bonded to the bonding point P1 and the second terminal of the scan transistor 230. The cathode of the second diode 222 is electrically connected to the anode of the first diode 221. An anode of the second diode 222 is electrically connected to the operation voltage Vss. The first terminal of the storage capacitor 240 is electrically connected to the bonding point P1 and the second terminal of the scan transistor 230. The second terminal of the storage capacitor 240 is electrically connected to the operation voltage Vss.

During the manufacturing process of the electronic device 200, the first diode 221 and the second diode 222 may be formed in the electronic device 200 before disposing the tunable unit 210 or the varactor diode 211 to serve as (or form) a discharge path for electrostatic current (if electrostatic discharge occurs) of bonding point P1 (and/or the second terminal of scan transistor 230). In other words, in some embodiments of the disclosure, the electronic device 200 may not include the tunable unit 210 or the varactor diode 211. Furthermore, in some other embodiments of the disclosure, during the operation process of the electronic device 200 (i.e. the device running process), the first diode 221 and the second diode 222 may also provide an electrostatic protection function.

In the embodiment, for the bonding point P1, the first diode 221 and the second diode 222 form a series-connected reverse diode. In a normal operation, the first diode 221 and the second diode 222 may not be turned-on due to insufficient reverse bias voltage. When an electrostatic discharge occurs at the bonding point P1 and an electrostatic current is generated, and the first diode 221 and the second diode 222 may form a discharge path for electrostatic current to avoid damage to the scanning transistor 230 or its back-end circuit due to the electrostatic current. The first diode 221 and the second diode 222 may discharge the electrostatic current to the operation voltage Vss. The first diode 221 and the second diode 222 may provide a higher reverse bias withstand voltage effect.

FIG. 3 is a circuit diagram of an electronic device according to an embodiment of the disclosure. Referring to FIG. 3, the electronic device 300 includes a bonding point P1, a tunable unit 310, an electrostatic discharge protection circuit 320, a scan transistor 330, and a storage capacitor 340. The scan transistor 330 has a first terminal, a second terminal and a control terminal. In the embodiment, the first terminal of the scan transistor 330 is electrically connected to the circuit node P2. The second terminal of the scan transistor 330 is electrically connected to the bonding point P1, the tunable unit 310, the electrostatic discharge protection circuit 320 and the storage capacitor 340. In the embodiment, the tunable unit 310 includes a varactor diode 311. The first terminal of the varactor diode 311 is electrically connected to the bonding point P1. The second terminal of the varactor diode 311 is electrically connected to the operation voltage Vss. The electrostatic discharge protection circuit 320 includes a first diode 321 and a second diode 322. The first diode 321 is electrically connected to the bonding point P1 and the second terminal of the scan transistor 330. The second diode 322 is electrically connected to the first diode 321. The first diode 321 and the second diode 322 are connected in series. The anode of the first diode 321 is electrically connected to the bonding point P1. A cathode of the second diode 322 is electrically connected to a cathode of the first diode 321 and a second terminal of the scan transistor 330. An anode of the second diode 322 is electrically connected to the operation voltage Vss. The first terminal of the storage capacitor 340 is electrically connected to the bonding point P1 and the second terminal of the scan transistor 330. The second terminal of the storage capacitor 340 is electrically connected to the operation voltage Vss.

During the manufacturing process of the electronic device 300, the first diode 321 and the second diode 322 may be formed in the electronic device 300 before disposing the tunable unit 310 or varactor diode 311 to serve as (or form) a discharge path for electrostatic current (if electrostatic discharge occurs) of bonding point P1 (and/or the second terminal of scan transistor 330). In other words, in some embodiments of the disclosure, the electronic device 300 may not include the tunable unit 310 or the varactor diode 311. Furthermore, in some other embodiments of the disclosure, during the operation of the electronic device 300, the first diode 321 and the second diode 322 may also provide an electrostatic protection function.

In the embodiment, for the bonding point P1, the first diode 321 may form a forward diode, and the second diode 322 may form a reverse diode. During a normal operation, the second diode 322 may not be turned-on due to insufficient reverse bias. When bonding point P1 generates electrostatic current due to electrostatic discharge and the reverse bias voltage of the second diode 322 is sufficient to turned-on, the first diode 321 and the second diode 322 may form a discharge path for the electrostatic current to prevent the scan transistor 330 or its back-end circuit from being damaged by the electrostatic current. The first diode 321 and the second diode 322 may discharge the electrostatic current to the operation voltage Vss. From another perspective, when electrostatic discharge occurs at one terminal of the operation voltage Vss, the first diode 321 and the second diode 322 may also provide a discharge path, so as to prevent the scan transistor 330 or its back-end circuit from being damaged.

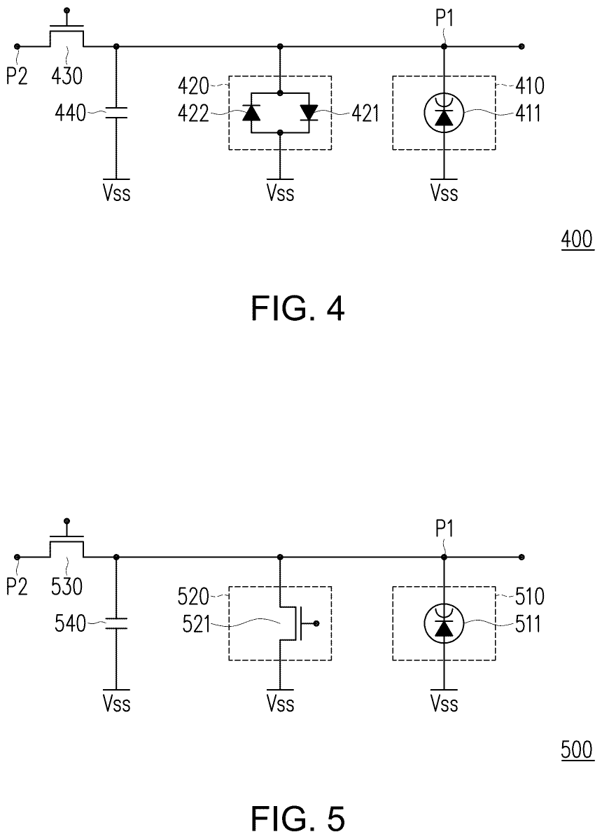

FIG. 4 is a circuit diagram of an electronic device according to an embodiment of the disclosure. Referring to FIG. 4, an electronic device 400 includes a bonding point P1, a tunable unit 410, an electrostatic discharge protection circuit 420, a scan transistor 430, and a storage capacitor 440. The scan transistor 430 has a first terminal, a second terminal and a control terminal. In the embodiment, the first terminal of the scan transistor 430 is electrically connected to the circuit node P2. The second terminal of the scan transistor 430 is electrically connected to the bonding point P1, the tunable unit 410, the electrostatic discharge protection circuit 420 and the storage capacitor 440. In the embodiment, the tunable unit 410 includes a varactor diode 411. The first terminal of the varactor diode 411 is electrically connected to the bonding point P1. The second terminal of the varactor diode 411 is electrically connected to the operation voltage Vss. The electrostatic discharge protection circuit 420 includes a first diode 421 and a second diode 422. The first diode 421 is electrically connected to the bonding point P1 and the second terminal of the scan transistor 430. The second diode 422 is electrically connected to the bonding point P1 and the second terminal of the scan transistor 430. The first diode 421 and the second diode 422 are connected in parallel. An anode of the first diode 421 is electrically connected to the bonding point P1 and the second terminal of the scan transistor 430. The cathode of the first diode 421 is electrically connected to the operation voltage Vss. A cathode of the second diode 422 is electrically connected to the bonding point P1 and the second terminal of the scan transistor 430. An anode of the second diode 422 is electrically connected to the operation voltage Vss. The first terminal of the storage capacitor 440 is electrically connected to the bonding point P1 and the second terminal of the scan transistor 430. The second terminal of the storage capacitor 440 is electrically connected to the operation voltage Vss.

During the manufacturing process of the electronic device 400, the first diode 421 and the second diode 422 may be formed in the electronic device 400 before disposing the tunable unit 410 or the varactor diode 411 to serve as (or form) a discharge path for electrostatic current (if electrostatic discharge occurs) of bonding point P1 (and/or the second terminal of scan transistor 430). In other words, in some embodiments of the disclosure, the electronic device 400 may not include the tunable unit 410 or the varactor diode 411. Furthermore, in some other embodiments of the disclosure, during the operation of the electronic device 400, the first diode 421 and the second diode 422 may also provide an electrostatic protection function.

In the embodiment, for the bonding point P1, the first diode 421 may form a forward diode, and the second diode 422 may form a reverse diode. When electrostatic discharge occurs in the bonding point P1 and an electrostatic current is generated, the first diode 421 may form a discharge path for the electrostatic current to prevent the scan transistor 430 or its back-end circuit from being damaged by the electrostatic current. The first diode 421 may discharge the electrostatic current to the operation voltage Vss. From another perspective, when electrostatic discharge occurs at one terminal of the operation voltage Vss, the second diode 422 may provide a discharge path to prevent the scan transistor 430 or its back-end circuit from being damaged.

FIG. 5 is a circuit diagram of an electronic device according to an embodiment of the disclosure. Referring to FIG. 5, an electronic device 500 includes a bonding point P1, a tunable unit 510, an electrostatic discharge protection circuit 520, a scan transistor 530 and a storage capacitor 540. The scan transistor 530 has a first terminal, a second terminal and a control terminal. In the embodiment, the first terminal of the scan transistor 530 is electrically connected to the circuit node P2. The second terminal of the scan transistor 530 is electrically connected to the bonding point P1, the tunable unit 510, the electrostatic discharge protection circuit 520 and the storage capacitor 540. In the embodiment, the tunable unit 510 includes a varactor diode 511. The first terminal of the varactor diode 511 is electrically connected to the bonding point P1. The second terminal of the varactor diode 511 is electrically connected to the operation voltage Vss. The electrostatic discharge protection circuit 520 includes a switch transistor 521. A first terminal of the switch transistor 521 is electrically connected to the bonding point P1 and a second terminal of the scan transistor 530. The second terminal of the switch transistor 521 is electrically connected to the operation voltage Vss. The control terminal of the switch transistor 521 is floating. The first terminal of the storage capacitor 540 is electrically connected to the bonding point P1 and the second terminal of the scan transistor 530. The second terminal of the storage capacitor 540 is electrically connected to the operation voltage Vss.

During the manufacturing process of the electronic device 500, the switch transistor 521 may be formed in the electronic device 500 before disposing the tunable unit 510 or the varactor diode 511 to serve as (or form) a discharge path for electrostatic current (if electrostatic discharge occurs) of bonding point P1 (and/or the second terminal of scan transistor 530). In other words, in some embodiments of the disclosure, the electronic device 500 may not include the tunable unit 510 or the varactor diode 511. Furthermore, in some other embodiments of the disclosure, during the operation of the electronic device 500, the switch transistor 521 may also provide an electrostatic protection function.

In the embodiment, for the bonding point P1, during a normal operation, the switch transistor 521 is not turned-on. When electrostatic discharge occurs in bonding point P1 and generates an electrostatic current, due to the coupling effect between the first terminal (i.e., the drain terminal or the source terminal) and the control terminal (i.e., the gate terminal) of the switch transistor 521, the high voltage generated by the electrostatic discharge may cause the switch transistor 521 to switch to the turn-on state, thereby forming a discharge path for the electrostatic current to prevent the scan transistor 530 or its back-end circuit from being damaged by the electrostatic current. The switch transistor 521 may discharge the electrostatic current to the operation voltage Vss. From another perspective, when electrostatic discharge occurs at one terminal of the operation voltage Vss, the switch transistor 521 may also provide a discharge path to prevent the scan transistor 530 or its back-end circuit from being damaged.

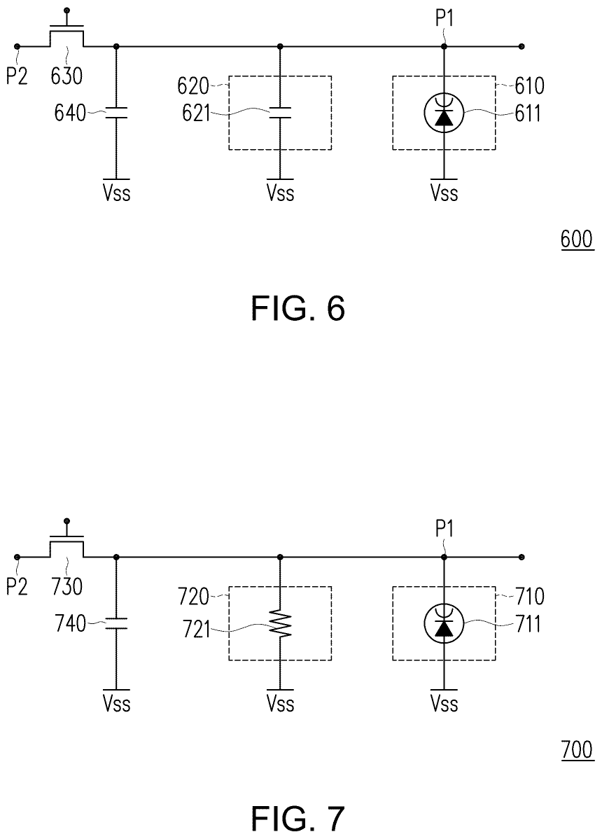

FIG. 6 is a circuit diagram of an electronic device according to an embodiment of the disclosure. Referring to FIG. 6, an electronic device 600 includes a bonding point P1, a tunable unit 610, an electrostatic discharge protection circuit 620, a scan transistor 630, and a storage capacitor 640. The scan transistor 630 has a first terminal, a second terminal and a control terminal. In the embodiment, the first terminal of the scan transistor 630 is electrically connected to the circuit node P2. The second terminal of the scan transistor 630 is electrically connected to the bonding point P1, the tunable unit 610, the electrostatic discharge protection circuit 620, and the storage capacitor 640. In the embodiment, the tunable unit 610 includes a varactor diode 611. The first terminal of the varactor diode 611 is electrically connected to the bonding point P1. The second terminal of the varactor diode 611 is electrically connected to the operation voltage Vss. The electrostatic discharge protection circuit 620 includes another storage capacitor 621. The first terminal of the storage capacitor 621 is electrically connected to the bonding point P1 and the second terminal of the scan transistor 630. The second terminal of the storage capacitor 621 is electrically connected to the operation voltage Vss. The first terminal of the storage capacitor 640 is electrically connected to the bonding point P1 and the second terminal of the scan transistor 630. The second terminal of the storage capacitor 640 is electrically connected to the operation voltage Vss.

During the manufacturing process of the electronic device 600, the storage capacitor 621 may be formed in the electronic device 600 before disposing the tunable unit 610 or the varactor diode 611 to serve as (or form) a discharge path for electrostatic current (if electrostatic discharge occurs) of bonding point P1 (and/or the second terminal of scan transistor 630). In other words, in some embodiments of the disclosure, the electronic device 600 may not include the tunable unit 610 or the varactor diode 611. Furthermore, in some other embodiments of the disclosure, during the operation of the electronic device 600, the storage capacitor 621 may also provide an electrostatic protection function.

In the embodiment, the storage capacitor 621 may have a higher capacitance value. For bonding point P1, when electrostatic discharge occurs in bonding point P1 and electrostatic current is generated, storage capacitor 621 may store the charge generated by the electrostatic discharge to reduce the amount of current generated by the electrostatic discharge, thereby preventing the scan transistor 630 or its back-end circuit from being damaged by the electrostatic current. From another perspective, when electrostatic discharge occurs at one terminal of the operation voltage Vss, the storage capacitor 621 may also store the charge generated by the electrostatic discharge to reduce the current generated by the electrostatic discharge, thereby preventing the scan transistor 630 or its back-end circuit from being damaged by the electrostatic current.

FIG. 7 is a circuit diagram of an electronic device according to an embodiment of the disclosure. Referring to FIG. 7, an electronic device 700 includes a bonding point P1, a tunable unit 710, an electrostatic discharge protection circuit 720, a scan transistor 730 and a storage capacitor 740. The scan transistor 730 has a first terminal, a second terminal and a control terminal. In the embodiment, the first terminal of the scan transistor 730 is electrically connected to the circuit node P2. The second terminal of the scan transistor 730 is electrically connected to the bonding point P1, the tunable unit 710, the electrostatic discharge protection circuit 720 and the storage capacitor 740. In the embodiment, the tunable unit 710 includes a varactor diode 711. The first terminal of the varactor diode 711 is electrically connected to the bonding point P1. The second terminal of the varactor diode 711 is electrically connected to the operation voltage Vss. The electrostatic discharge protection circuit 720 includes a resistor 721. A first terminal of the resistor 721 is electrically connected to the bonding point P1 and a second terminal of the scan transistor 730. The second terminal of the resistor 721 is electrically connected to the operation voltage Vss. The first terminal of the storage capacitor 740 is electrically connected to the bonding point P1 and the second terminal of the scan transistor 730. The second terminal of the storage capacitor 740 is electrically connected to the operation voltage Vss.

During the manufacturing process of the electronic device 700, the resistor 721 may be formed in the electronic device 700 before disposing tunable unit 710 or varactor diode 711 to serve as (or form) a discharge path for electrostatic current (if electrostatic discharge occurs) of bonding point P1 (and/or the second terminal of scan transistor 730). In other words, in some embodiments of the disclosure, the electronic device 700 may not include the tunable unit 710 or the varactor diode 711. Furthermore, in some other embodiments of the disclosure, during the operation of the electronic device 700, the resistor 721 may also provide an electrostatic protection function.

In the embodiment, for the bonding point P1, during a normal operation, the resistor 721 may only allow a small amount of current to pass or no current to pass. When electrostatic discharge occurs at bonding point P1 and generates an electrostatic current, the high current (or high voltage) generated by the electrostatic discharge may be released to the operation voltage Vss through resistor 721, thereby forming a discharge path for the electrostatic current to prevent the scan transistor 730 or its back-end circuit from being damaged by the electrostatic current. From another perspective, when electrostatic discharge occurs at one terminal of the operation voltage Vss, the resistor 721 may also provide a discharge path to prevent the scan transistor 730 or its back-end circuit from being damaged.

In summary, the electronic device of the disclosure may release the electrostatic current generated in the bonding point through the electrostatic discharge protection circuit to effectively protect the scan transistor electrically connected to the bonding point or its back-end circuit from being damaged.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a bonding point;
an electrostatic discharge protection circuit, electrically connected to the bonding point; and
a scan transistor, having a first terminal, a second terminal and a control terminal, wherein the second terminal of the scan transistor is electrically connected to the bonding point and the electrostatic discharge protection circuit.

2. The electronic device according to claim 1, further comprising:
a tunable unit, electrically connected to the bonding point.

3. The electronic device according to claim 2, further comprising:
a storage capacitor, electrically connected between the bonding point and the tunable unit.

4. The electronic device according to claim 3, wherein a first terminal of the storage capacitor is electrically connected to the bonding point, and a second terminal of the storage capacitor is electrically connected to an operation voltage.

5. The electronic device according to claim 3, wherein the electrostatic discharge protection circuit comprises:
another storage capacitor, electrically connected between the bonding point and the tunable unit.

6. The electronic device according to claim 5, wherein a first terminal of the another storage capacitor is electrically connected to the bonding point, and a second terminal of the another storage capacitor is electrically connected to an operation voltage.

7. The electronic device according to claim 2, wherein the tunable unit comprises a varactor diode.

8. The electronic device according to claim 2, wherein the electrostatic discharge protection circuit is formed in the electronic device before disposing the tunable unit to serve as a discharge path of the bonding point.

9. The electronic device according to claim 1, wherein the electrostatic discharge protection circuit comprises:
a first diode, electrically connected to the bonding point; and
a second diode, electrically connected to the first diode.

10. The electronic device according to claim 9, wherein a cathode of the first diode is electrically connected to the bonding point, a cathode of the second diode is electrically connected to an anode of the first diode, and an anode of the second diode is electrically connected to an operation voltage.

11. The electronic device according to claim 9, wherein an anode of the first diode is electrically connected to the bonding point, a cathode of the second diode is electrically connected to a cathode of the first diode, and an anode of the second diode is electrically connected to an operation voltage.

12. The electronic device according to claim 11, wherein the operation voltage is a ground voltage.

13. The electronic device according to claim 9, wherein an anode of the first diode is electrically connected to the bonding point, a cathode of the first diode is electrically connected to an operation voltage, a cathode of the second diode is electrically connected to the bonding point, and an anode of the second diode is electrically connected to the operation voltage.

14. The electronic device according to claim 1, wherein the electrostatic discharge protection circuit comprises:
a switch transistor, wherein a first terminal of the switch transistor is electrically connected to the bonding point, a second terminal of the switch transistor is electrically connected to an operation voltage, and a control terminal of the switch transistor is floating.

15. The electronic device according to claim 1, wherein the electrostatic discharge protection circuit comprises:
a resistor, electrically connected between the bonding point and a tunable unit.

16. The electronic device according to claim 15, wherein a first terminal of the resistor is electrically connected to the bonding point, and a second terminal of the resistor is electrically connected to an operation voltage.

17. The electronic device according to claim 1, further comprising:
a substrate, comprising a plurality of pixel units,
wherein each of the plurality of pixel units comprises the bonding point, the electrostatic discharge protection circuit and the scan transistor.

18. The electronic device according to claim 1, wherein the scan transistor is a thin film transistor.

19. The electronic device according to claim 1, wherein the scan transistor is an N-type transistor.

20. The electronic device according to claim 1, wherein the scan transistor is a P-type transistor.
